(19) United States
(12) Patent Application Publication
(10) Pub. No.: US 2025/0167518 A1
(43) Pub. Date: May 22, 2025

(54) INTEGRATED HIGH-POWER LASER EMISSION DEVICE

(71) Applicant: Commissariat à l'Energie Atomique et aux Energies Alternatives, Paris (FR)

(72) Inventors: Sylvain GUERBER, Grenoble cedex 09 (FR); Benoit CHARBONNIER, Grenoble cedex 09 (FR)

(73) Assignee: Commissariat à l'Energie Atomique et aux Energies Alternatives, Paris (FR)

(21) Appl. No.: 18/949,039

(22) Filed: Nov. 15, 2024

(30) Foreign Application Priority Data
Nov. 17, 2023 (FR) 2312669

(51) Int. Cl. H01S 5/14; H01S 5/40

(52) U.S. Cl. CPC H01S 5/141; H01S 5/4012; H01S 5/4062

(57) ABSTRACT

Laser emission device integrated into a substrate, comprising:
a primary waveguide formed in the substrate and extending from a primary reflector;
a plurality of secondary waveguides optically connected to the primary waveguide, and extending between a coupling end, optically connected to the primary waveguide, and a secondary reflector;
the device being characterized in that each secondary waveguide comprises a gain medium, connected to a laser-pumping system and placed between the coupling end and the secondary reflector of said secondary waveguide
so that the device forms as many Fabry-Pérot cavities as secondary waveguides;
the device comprising an extractor, for extracting light from the device, at the resonant wavelength. FIG. 2.

### TECHNICAL FIELD

The technical field of the invention is integrated optics and more precisely the design of a high-power laser emission circuit intended to be used, non-limitingly, in LIDAR or telecom applications, or in other photonic applications.

### PRIOR ART

In the field of optics, technologies allowing large-scale fabrication and assembly are being moved towards. By integrating optical components into a single chip, it is possible to reduce system size and cost while increasing system performance.

In the field of LIDARS, for example, use of wavelength-modulated laser sources is common. According to the principles of FMCW (acronym of frequency-modulated continuous-wave), it is possible to carry out continuous modulation of emission wavelength, for example according to a triangular wave, as shown in FIG. 1. Part of an emitted laser beam is sampled, and directed to a photodetector. The laser beam reflected by a target is also directed to the photodetector. Since the sampled beam and the reflected beam are coherent, their interference may be detected by the photodetector, and results in a frequency difference directly proportional to the distance of the target. Operation of such devices is for example described in the publication by C. Poulton “Coherent solid-state LIDAR with silicon photonic optical phased arrays”.

Wavelength-modulated lasers may also be used in the field of optical telecommunications.

Irrespectively of whether it is a question of LIDAR or telecoms applications, compact systems having a high emission power, for example greater than 100 mW, are sought. Until now, on-chip laser sources have not allowed such a power to be obtained. Hybrid systems allow emission power to be increased, by way of a coherent combination of beams emitted by various laser sources. The publications Zhu. Y “Loss induced coherent combining in InP—Si3N4 hybrid platform”, Sci. Rep., Vol. 8, No. 1, Art. No. 1, January 2018 and Zeng S. “Watt-level beam combined diode laser systems in a chip scale hybrid photonic platform”, Optics Express, Vol. 30, No. 13/20, June 2022, describe hybrid architectures in which a plurality of laser sources are transferred to a photonic chip. The beams emitted by each source are combined, in the substrate, so as to obtain a high-power beam. However, such architectures have the drawback of a high fabrication cost, because of the bond that it is necessary to form, between each laser source and the substrate. Another difficulty is the alignment between each laser source and the substrate, which may be tricky and cause losses.

The invention described below makes it possible to obtain a laser source integrated into a monolithic substrate. Depending on the arrangement, either a high-power laser source or a plurality of laser sources is obtained. Preferably, the laser source is continuously wavelength modulated, allowing it to be used in lidars.

### SUMMARY OF THE INVENTION

One subject of the invention is a laser emission device, integrated into a substrate, comprising:
a primary waveguide, formed in the substrate, and extending from a primary reflector, the primary reflector being configured to reflect light in a reflection spectral band;
a plurality of secondary waveguides, optically connected to the primary waveguide, each secondary waveguide extending between a coupling end, optically connected to the primary waveguide, and a secondary reflector, each secondary reflector being configured to reflect light in the reflection spectral band;
the device being characterized in that each secondary waveguide is optically coupled to a gain medium connected to a laser-pumping system, the gain medium being conducive to laser emission under the effect of pumping exerted by the laser-pumping system, the gain medium being placed between the coupling end and the secondary reflector of said secondary waveguide
so that the device forms as many Fabry-Pérot cavities as secondary waveguides, each Fabry-Pérot cavity being configured to allow multiple reflections of light at a given resonant wavelength, in the reflection spectral band, between the primary reflector and each secondary reflector;
the device comprising an extractor, for extracting light from the device, at the resonant wavelength, said resonant wavelength forming an emission wavelength of the device.

According to one embodiment, the primary reflector or each secondary reflector is adjustable, so as to modulate the reflection spectral band.

According to one possibility, the reflection spectral band of the primary reflector is adjustable, the primary reflector being a Bragg mirror, coupled to a modulator configured to modulate a refractive index in said Bragg mirror. Each secondary reflector may reflect light in a set secondary reflection spectral band wider than the reflection spectral band of the primary reflector and containing the latter spectral band.

According to one possibility, the reflection spectral band of each secondary reflector is adjustable, each secondary reflector being a Bragg mirror, coupled to a modulator configured to modulate a refractive index in said Bragg mirror. The primary reflector may reflect light in a set reflection spectral band wider than the reflection spectral band of each secondary reflector and containing the latter spectral band.

Preferably, at least one secondary waveguide comprises a secondary phase modulator, configured to modulate a refractive index along a portion of said secondary waveguide, the secondary phase modulator being placed between the coupling end of said secondary waveguide and the secondary reflector of said secondary waveguide, so as to modulate an optical path length in said secondary waveguide.

Preferably, each secondary waveguide comprises a secondary phase modulator, configured to modulate a refractive index along a portion of said secondary waveguide, the secondary phase modulator being placed between the coupling end of said secondary waveguide and the secondary reflector of said secondary waveguide, so as to modulate an optical path length in each secondary waveguide.

The primary waveguide may comprise a primary phase modulator, configured to modulate a refractive index along a portion of the primary waveguide, the primary phase modulator being placed between each secondary waveguide and the primary reflector, so as to modulate the resonant wavelength of each Fabry-Pérot cavity of the device.

### According to One Possibility:

the primary reflector reflects more than 90% of the light, in the reflection spectral band;
each secondary reflector transmits at least 20% of the light, in the reflection spectral band, so that the secondary reflector forms the extractor of the device.

### According to One Possibility:

each secondary reflector reflects more than 90% of the light, in the reflection spectral band;
the primary reflector transmits at least 20% in the reflection spectral band, so that the primary reflector forms the extractor of the device.

The primary waveguide may be formed by a first material, and surrounded by a first auxiliary material, the refractive index of which is lower than the refractive index of the first material.

Each secondary waveguide may be formed by a second material, and surrounded by a second auxiliary material, the refractive index of which is lower than the refractive index of the second material.

### According to One Possibility:

the first material is identical to the second material;
the first auxiliary material is identical to the second auxiliary material.

### According to One Possibility:

the first material and the second material are Si;
the first auxiliary material and the second auxiliary material are SiO2.

### According to One Possibility:

the first material is SiN;
the second material is Si;
the first auxiliary material is identical to the second auxiliary material.

Preferably, the primary waveguide and at least one secondary waveguide, or each secondary waveguide, are formed in the same substrate, each gain medium being transferred to said substrate.

The invention will be better understood on reading the description of the examples of embodiment presented, in the remainder of the description, with reference to the figures listed below.

### FIGURES

FIG. 1 shows an example of continuous wavelength modulation. The y-axis corresponds to the wavelength and the x-axis corresponds to time.

FIG. 2 shows a first embodiment.

FIGS. 3A and 3B schematically show a substrate cross section through the active material.

FIG. 4A schematically shows a reflection spectral band of a narrow and adjustable primary reflector, included in the wide reflection spectral band of a secondary reflector. The light energy propagated inside the Fabry-Pérot cavity formed by the primary reflector and the secondary reflector has also been shown.

FIG. 4B shows a configuration in which the reflection spectral band of the secondary reflector is coincident with a resonant wavelength of the Fabry-Pérot cavity.

FIG. 4C shows a configuration in which, with respect to FIG. 4B, the reflection spectral band of the secondary reflector has been modified.

FIG. 4D shows a configuration in which, with respect to FIG. 4C, the resonant wavelength of the Fabry-Pérot cavity has been modified.

FIG. 5 schematically shows a second embodiment.

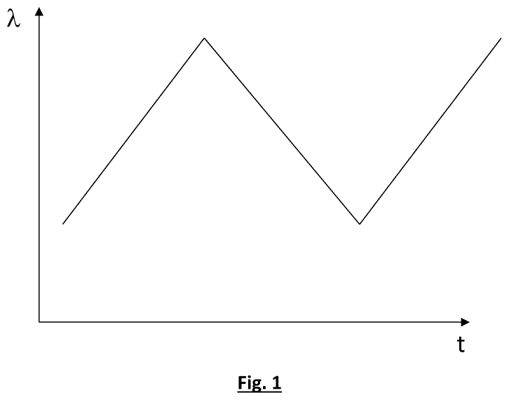

### DISCLOSURE OF PARTICULAR EMBODIMENTS

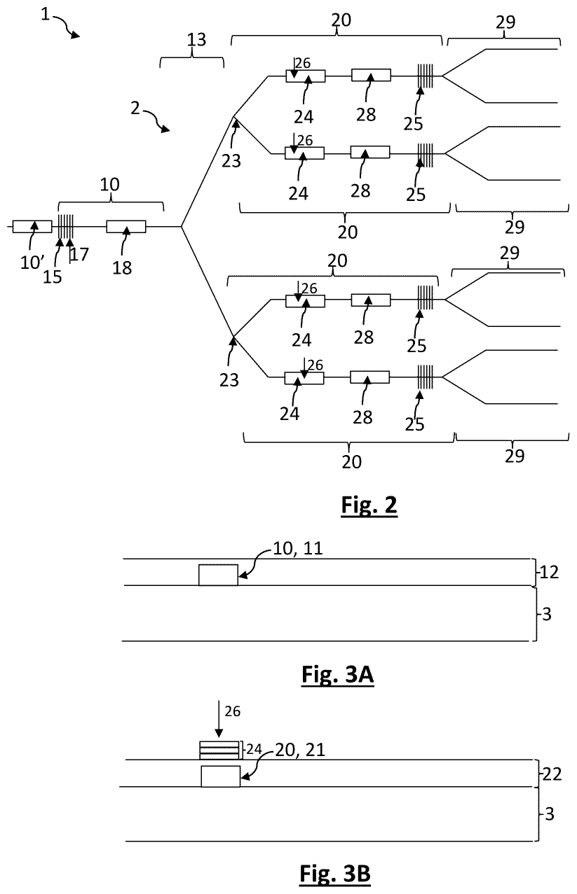

FIG. 2 schematically shows a first embodiment of a laser emission device 1 according to the invention. The device 1 is formed in a monolithic substrate 2. FIG. 2 represents a cross-sectional view of the device, in the plane of the substrate. The substrate 2 is for example an SOI substrate (SOI being the acronym of silicon on insulator). SOI substrates are well-known substrates in microelectronics, but they are also widely used in the fabrication of optical integrated circuits. Silicon is transparent at telecom wavelengths (1.3 μm-1.5 μm), and the high index contrast with its oxide (n_{Si}=3.51 and n_{SIO2}=1.45 i.e. Δn=n_{Si}-n_{SIO2}=2) makes it suitable for compact passive functions: mirrors, waveguides, resonant cavities. In addition, current fabrication processes are well characterized and allow production of substrates of large size.

Other types of substrates may be used, for example SiNOI (acronym of silicon nitride on insulator) or LNOI (acronym of lithium niobate on insulator) substrates.

The device comprises a primary waveguide 10 formed in the substrate and extending from a primary reflector 15 configured to reflect a wavelength of interest. In the examples described, the primary reflector 15 is a Bragg mirror, called the primary Bragg mirror. Other types of reflectors, for example Sagnac loops, are conceivable. The primary waveguide 10 is formed from a first material 11, in the present case Si, around which extends a first auxiliary material 12, in the present case SiO2. Other variants are described below.

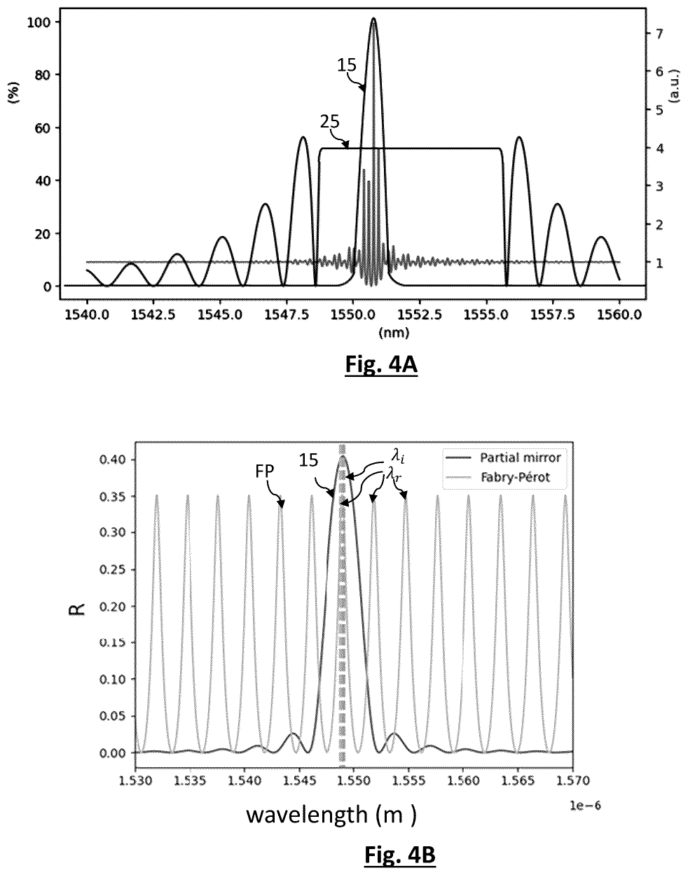

The primary waveguide 10 is formed by conventional photolithography/etching techniques. It is typically produced by etching the surface silicon layer of an SOI wafer, the latter making contact with an oxide layer 3. The Si waveguide resulting from the etching is then covered with an upper layer of a material 12 of lower index, SiO2 for example. The upper layer may be thinned and planarized. The thickness of the upper layer may be reduced to 100 nm. The channel is placed on the SiO2 layer 3. One example of channel geometry is described below, with reference to FIGS. 3A and 3B. The height of the waveguide 10 is typically between 220 nm and 500 nm, and its width may vary between 100 nm and 5 μm.

In a manner known per se, the primary Bragg mirror 15 is formed from a periodic alternation of two materials having different respective refractive indices. The periodic variation of the index generates a set of reflections that add up when they are in phase. In this example, the primary Bragg mirror 15 is formed by partially etching the silicon and then depositing SiO2. The periodicity of the etched areas determines a reflection spectral band, in which the Bragg mirror reflects light, the period being of the order of a few hundred nanometres. The number of periods is typically from several tens to several hundred or even thousands.

In this Example:
the primary Bragg mirror 15 is a mirror having a narrow reflection spectral band, the full width at half maximum of the reflection spectral band for example being less than 1 nm. The reflection spectral band is centred on the wavelength of interest λᵢ.
the primary Bragg mirror 15 is a total mirror, in the sense that it reflects almost all the light in the reflection spectral band. By almost all, what is meant is more than 90%, or even more than 95%, or indeed more than 99%.
the primary Bragg mirror 15 is adjustable, the reflection spectral band being variable. The variation in the reflection spectral band is obtained via modulation, under the effect of a modulator 17, of the refractive indices of the materials forming the Bragg mirror. Such modulation may be obtained via a local temperature variation, the modulator of the Bragg mirror 17 then being a resistive heater. The modulation may also be obtained via local injection of charge into the Bragg mirror. Specifically, the refractive index of a semiconductor depends on charge density. In FIG. 2, the modulator 17 of the primary Bragg mirror has been represented by an arrow.

The device 1 comprises a plurality of secondary waveguides 20, the structure of which is preferably, but not necessarily, identical to the structure of the primary waveguide 10: same material, same dimensions. Generally, each secondary waveguide 20 is formed from a second material 21, in the present case Si, around which extends a second auxiliary material 22, in the present case SiO2.

In this example, the device 1 comprises four secondary waveguides 20. The number of secondary waveguides may be between 2 and 10, or even several tens.

Each secondary waveguide 20 extends between a coupling end 23, intended to be optically connected to the primary waveguide 10, and a secondary reflector 25. In this example, the secondary reflector is a Bragg mirror, called the secondary Bragg mirror. Preferably, the secondary Bragg mirrors are identical to one another. They are preferably formed with the same materials as the primary Bragg mirror 15, so as to reflect light at the wavelength of interest defined by the primary Bragg mirror 15. Preferably, the reflection spectral band of each secondary Bragg mirror 25 is identical to, or wider than, that of the primary reflector, and comprises the reflection spectral band of the primary reflector 15. In this example:
each secondary Bragg mirror 25 is a mirror having a wide reflection spectral band, the full width at half maximum of the reflection spectral band for example being greater than or equal to 10 nm.
each secondary Bragg mirror 25 is a partial mirror, in the sense that it reflects light in the reflection spectral band only partially. By partially, what is meant is less than 80%, or even less than 50%, and for example 40%. Unreflected light is transmitted to a photonic circuit. For example, each secondary Bragg mirror 25 is connected to one of the inputs of an optical phased array (OPA) that allows, in the context of a LiDAR system, the beam to be scanned through space. The secondary Bragg mirrors form the light extractor of the device.

The length of each Bragg mirror may be between a few hundred microns and several millimetres.

It goes without saying that the reflection spectral band of the primary Bragg mirror extends into the reflection spectral band of each secondary Bragg mirror. Reflections of at least one wavelength of interest λᵢ, which corresponds to the intersection of the reflection spectral band of the primary Bragg mirror and of each secondary Bragg mirror, are thus obtained.

Transmission waveguides 13 extend between the primary waveguide 10 and each secondary waveguide 20, the function of which transmission waveguides is to ensure optical coupling between the primary waveguide 15 and each secondary waveguide 25. A coupler is used at each coupling end 23 to connect/combine the beams delivered by the various secondary guides 20 to the primary waveguide 10. The coupler may for example be a directional coupler or a multimode interferometer (MMI).

Each secondary waveguide 20 forms, with the primary waveguide 10, a Fabry-Perot cavity, allowing successive reflections of light at the wavelength of interest λᵢ. The wavelength of interest 1; must also correspond to a resonant wavelength λᵣ of each Fabry-Pérot cavity, as described below. In this example, the wavelength of interest 1; is defined by the Bragg mirror having the narrowest reflection spectral band. Here this mirror is the primary Bragg mirror 15. It may be seen that the device allows formation of as many Fabry-Pérot cavities as secondary waveguides 20. Each Fabry-Perot cavity is formed by the primary waveguide 10 and a secondary waveguide 20.

An important aspect of the invention is that each secondary waveguide is optically coupled to a gain medium 24. The gain medium 24, or active medium, is a medium that emits laser light under the effect of pumping. It may for example be a question of layers of III-V materials formed facing the secondary waveguide 20.

The light generated by the gain medium 24 is injected into the secondary waveguide 20, to which it is optically coupled. The gain medium 24 may be separated from the secondary waveguide 20 by a low-index bonding layer. It is known that stacks of III-V materials of AlGaAs/GaAs type allow emission in the 600-800 nm range, and that stacks of III-V InGaAsP/InP materials allow emission in the 1300/1500 nm range.

The gain layer 24 is produced by transferring, to the substrate, an epitaxially grown III-V laser, allowing formation of active layers of a few microns. This stack is then etched to form a waveguide above the photonic guide 20, itself also being optimized to facilitate transfer of light to/from the III-V guide. Transfer of layers of III-V materials to an Si waveguide formed on an SOI substrate is for example described in Roelkens G. “III-V/silicon photonics for on-chip and inter-chip optical interconnect”, Laser Photonics Rev. 4 No. 6, 751-779 (2010).

FIGS. 3A and 3B schematically show cross-sectional views of the substrate 2, level with the primary waveguide 10 and with the secondary waveguide 20 respectively. FIG. 3B schematically shows a cross-sectional view of a gain medium 24. The gain medium is configured to be coupled to a pumping system 26. The latter is actuated to obtain a population inversion of the charge carriers in the active material. It may be a question of optical pumping, in which case the inversion results from absorption of a pump laser beam. Preferably, it may be a question of electrical pumping, allowing charge carriers to be injected via a current into a p-i-n diode the i-region of which (i standing for intrinsic) is formed by the active material. Electrical pumping is simpler to implement.

The gain medium 24 is placed between the coupling end 23 and the secondary Bragg mirror 25. This makes it possible to emit, at the wavelength of interest, laser light that is then amplified by the Fabry-Pérot cavity, because each gain medium 24 is placed between two Bragg mirrors: the primary Bragg mirror 15 and a secondary Bragg mirror 25.

The emission device 1 allows emission of spatially distributed high-power laser light, the emission resulting from the transmission of each secondary Bragg mirror 25. In the example shown, emission waveguides 29 allow the emission of light from the device. As described above, the reflection by the secondary Bragg mirrors 25 is partial. Light that is not reflected is transmitted. Each secondary Bragg mirror 25 is placed between a secondary waveguide 20 and at least one emission waveguide 29. The respective light waves emitted by each secondary waveguide 20 are coherent, at the wavelength of interest.

Use of a modulator of the primary Bragg mirror 17 makes it possible to vary the emission wavelength of the device. A control unit 30 makes it possible to control the modulator 17, so as to control the reflection spectral band of the primary mirror 15.

Each Fabry-Pérot cavity is defined by resonant wavelengths, defined by the relationship:

$${λ}_{r} = \frac{2 L n}{m}$$

where
λᵣ is the resonant wavelength;
L is the length of the Fabry-Pérot cavity;
n is the effective index of the waveguide formed by the primary waveguide 10, the transition waveguide 13 and the secondary waveguide 20:
m is an integer designating a resonant mode.

In order to obtain a continuous variation in the emission wavelength of the device, it is advantageous for the device to comprise, in each Fabry-Pérot cavity, at least one modulator, called the phase modulator, so as to modulate the resonant wavelength λᵣ so that it corresponds to the wavelength of interest λᵢ reflected by the Bragg mirrors.

In each Fabry-Pérot cavity, at least one of the reflectors is configured so as to address only one resonant peak.

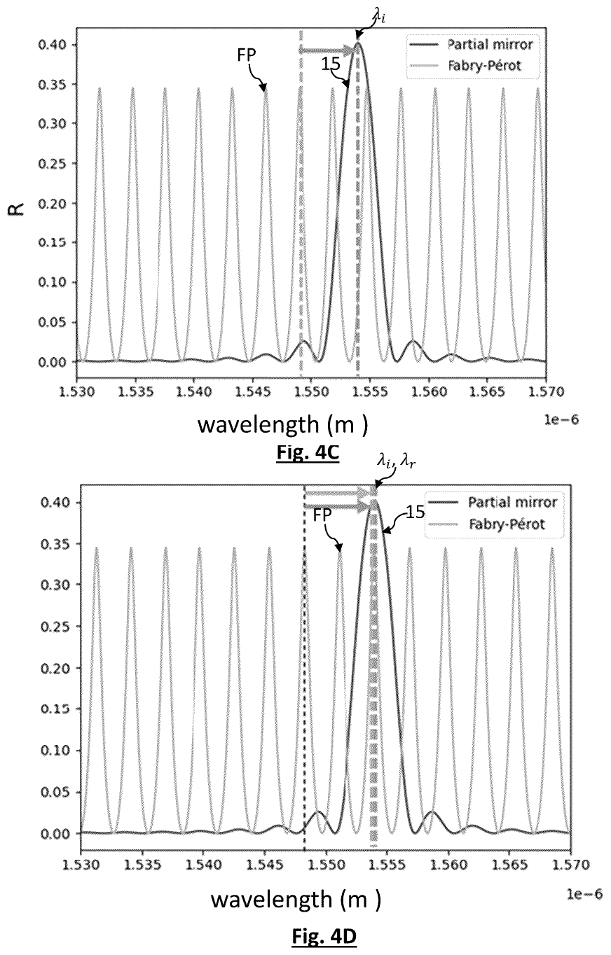

FIGS. 4A to 4D illustrate a variation in the emission wavelength of the device. FIG. 4A shows the reflection spectral band of the primary Bragg mirror 15, and the reflection spectral band of each secondary Bragg mirror 25. It may be seen that the primary Bragg mirror 15 reflects of the order of 100% of the light, in a narrow spectral band, while each secondary Bragg mirror 25 reflects of the order of 50% of the light, in a wide spectral band, containing the narrow spectral band of the primary Bragg mirror 15. In FIG. 4A, the left-hand y-axis represents reflectance (%), and the x-axis represents wavelength (nm). Also shown is an intensity of light propagating through the Fabry-Pérot cavity formed by the primary Bragg mirror 15 and by the secondary Bragg mirror 25 at various wavelengths (right-hand y-axis, arbitrary units).

FIG. 4B shows the spectral band of the primary Bragg mirror 15, centred on a wavelength of interest λᵢ close to 1550 nm. Resonant wavelengths λᵣ of each Fabry-Perot cavity have also been shown, in the curve referenced FP. In the example in FIG. 4B, the wavelength of interest λᵢ corresponds to a resonant wavelength λᵣ and to the emission wavelength of the device. In FIG. 4B, the left-hand y-axis represents reflectance (%), and the x-axis represents wavelength (m).

FIG. 4C shows a shift of the spectral band of the primary Bragg mirror 15. The emission wavelength of the device corresponds to a resonant wavelength λᵣ forming part of the reflection spectral band of the Bragg mirror, i.e. 1555 nm. This wavelength corresponds to the resonant wavelength of the Fabry-Pérot cavity included in the reflection spectral band. A discrete variation in the emission wavelength is then observed, with a jump from about 1548 nm (FIG. 4B) to 1555 nm (FIG. 4C). This makes it possible to modify the emission wavelength of the device, to discrete values. The emission wavelength of the device then corresponds to a resonant wavelength present in the reflection spectral band of the primary Bragg mirror. In FIG. 4C, the left-hand y-axis represents reflectance (%), and the x-axis represents wavelength (m). The dashed lines represent the maxima of the reflection spectral bands of the primary Bragg mirror before and after the shift, respectively.

In order to obtain a continuous variation in the emission wavelength of the device, it is advantageous to accompany the variation in the reflection spectral band of the Bragg mirror 15 by a gradual variation in the resonant wavelengths λᵣ of the Fabry-Perot cavity, as shown in FIG. 4D. This ensures that a resonant wavelength λᵣ always corresponds to a maximum of the reflection spectral band of the Bragg mirror 15.

The variation in the resonant wavelength λᵣ of each Fabry-Pérot cavity of the device may be obtained by placing a modulator, called the primary phase modulator 18, on the primary waveguide 10. The primary phase modulator 18 is configured to make the refractive index of the primary waveguide 10 vary. The variation in refractive index may be obtained via localized heating, or via injection of charge. The primary phase modulator 18 may extend a length between a few hundred microns and a few millimetres.

With a silicon guide, it is estimated that a spectral shift of as much as 0.1 nm per K may be obtained. Thus, by modifying the temperature by 30° C., a spectral shift of 3 nm may be generated.

Secondary phase modulators 28 may be placed in each secondary waveguide. Their function is to equalize optical path lengths in each secondary waveguide 20. It will be noted that it is also possible to directly modulate the current (pump electrical signal) of each gain medium 24, this causing a variation in the charge density in the gain medium, and therefore a modification of optical path length. Individual adjustment makes it possible to take into account variabilities resulting from device fabrication. Placing secondary phase modulators 28 in each secondary waveguide allows individual adjustment of each Fabry-Pérot cavity of the device, so that all the cavities have, at any given time, the same resonant wavelength λᵣ.

Alternatively, the device schematically shown in FIG. 2 may be such that the primary mirror 15 is set, and has a wide reflection spectral band, while each secondary mirror 25 is variable, and has a narrow reflection spectral band. However, such a configuration has the drawback of requiring a plurality of secondary mirrors 25 to be controlled simultaneously. The configuration shown in FIG. 2 has the advantage of requiring only a single Bragg mirror (in the present case Bragg mirror 15) to be driven, simultaneously with control of the variation in the resonant wavelength of each Fabry-Perot cavity using the primary modulator 18 and/or secondary modulators 28.

The device comprises a photodiode 10′, which is placed at the exit of the primary mirror 10, and which detects leaked light transmitted by the latter. When the optical path lengths of the secondary waveguides 20 are equal, each Fabry-Pérot cavity of the device allows emission of phase-locked laser light, this leading to a substantial increase in laser power. This increase may be detected by the photodiode 10′, and indicates correct operation of the device. The optical path length of each Fabry-Pérot cavity may be equalized sequentially, by adjusting each modulator and each gain medium one by one, to maximize the power received by the photodiode 10′.

The device described with reference to FIG. 2 is intended to deliver a coherent laser emission that is spatially distributed, to each emission guide 29 connected to a secondary guide 20. One advantage is that the only light guide transporting all the laser power is the primary light guide 10: the maximum power of the laser is transported over a relatively short length, and typically over a few hundred microns.

Concentration of a high power density in a single Si waveguide may result in beam absorption via two-photon absorption (TPA). This may lead to a limitation of the optical power emitted by the device. Distributing the beam between various secondary waveguides 20 makes it possible to reduce the impact of this type of absorption.

According to one possibility, the primary waveguide 10, in which laser power is concentrated, may be formed from a material that is less sensitive to TPA and more suitable for transport of light of high power. Thus, the first material 11, forming the primary waveguide, may be made of SiN, which does not exhibit TPA at the wavelengths of interest.

The device described with reference to FIG. 2 allows laser power to be increased, while multiplying points of emission. It may be used in LIDAR systems, to increase their range.

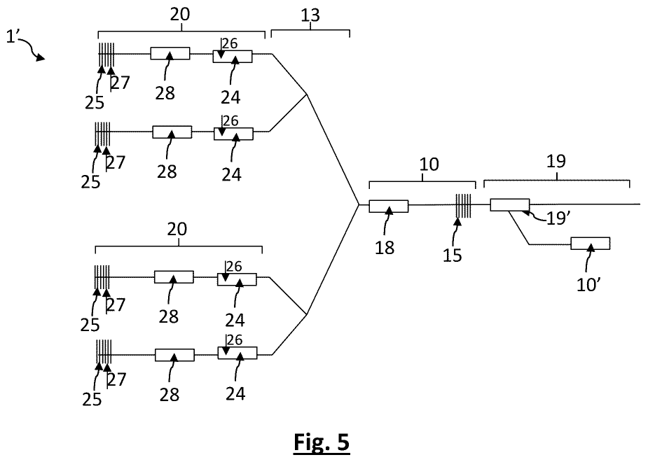

According to another possibility, shown in FIG. 5, the invention may be employed to concentrate coherent laser waves, so as to produce a high-power beam. In FIG. 5, components that are not described below are identical to those described with reference to FIG. 2, and have the same function.

A notable difference with respect to the device shown in FIG. 2 is that each secondary reflector 25 is totally reflective (reflection coefficient greater than 90%, or even close to 100%), while the primary reflector 15 is partially reflective, the reflection coefficient being less than 80%, or even than 50%. Thus, the light is emitted by an emission waveguide 19 connected to the primary waveguide 10. The primary reflector 15 has a light-extracting function. The primary reflector 15 extends between the primary waveguide 10 and the emission waveguide 19. The light emission is formed from light transmitted by the primary Bragg mirror. A coupler 19′ makes it possible to direct a small percentage of light, for example 1%, to the photodiode 10′. The latter is used to track the laser power emitted by the device. It makes it possible to verify that the various lasers have been phase-locked.

Regardless of the embodiment, the device may be used to emit a high-power laser beam, without necessarily varying the emission wavelength over time. In this case, it is not necessary for at least one reflector, in the present case the primary reflector, to be modular. Likewise, it is not necessary to modulate the resonant frequency of the Fabry-Pérot cavities. The primary modulator 18 is not required. Use of secondary modulators 28 remains preferable, for the purpose of adjusting the optical path lengths in each secondary waveguide 20. The device may be used for photonic-computing applications, in which mathematical operations are performed by generating destructive or constructive interference between a plurality of coherent laser beams. Constructive interference may correspond to an addition. Destructive interference corresponds to a subtraction.

1. A laser emission device integrated into a substrate, comprising:
a primary waveguide, formed in the substrate, and extending from a primary reflector, the primary reflector being configured to reflect light in a reflection spectral band;
a plurality of secondary waveguides, optically connected to the primary waveguide, each secondary waveguide extending between a coupling end, optically connected to the primary waveguide, and a secondary reflector, each secondary reflector being configured to reflect light in the reflection spectral band;
wherein
each secondary waveguide is optically coupled to a gain medium connected to a laser-pumping system, the gain medium being conducive to laser emission under the effect of pumping exerted by the laser-pumping system, the gain medium being placed between the coupling end and the secondary reflector of the secondary waveguide so that the device forms as many Fabry-Pérot cavities as secondary waveguides, each Fabry-Pérot cavity being configured to allow multiple reflections of light at a given resonant wavelength, in the reflection spectral band, between the primary reflector and each secondary reflector;
the device comprises an extractor, for extracting light from the device, at the resonant wavelength, said resonant wavelength forming an emission wavelength of the device;
the secondary waveguides define optical path lengths that are equal to one another.

2. The device according to claim 1, wherein the primary reflector or each secondary reflector is adjustable, so as to modulate the reflection spectral band.

3. The device according to claim 2, wherein the reflection spectral band of the primary reflector is adjustable, the primary reflector being a Bragg mirror, coupled to a modulator configured to modulate a refractive index in said Bragg mirror.

4. The device according to claim 3, wherein the secondary reflector reflects light in a set secondary reflection spectral band wider than the reflection spectral band of the primary reflector.

5. The device according to claim 4, wherein the reflection spectral band of each secondary reflector is adjustable, each secondary reflector being a Bragg mirror, coupled to a modulator configured to modulate a refractive index in said Bragg mirror.

6. The device according to claim 5, wherein the primary reflector reflects light in a set reflection spectral band wider than the reflection spectral band of each secondary reflector.

7. The device according to claim 1, wherein at least one secondary waveguide comprises a secondary phase modulator, configured to modulate a refractive index along a portion of said secondary waveguide, the secondary phase modulator being placed between the coupling end of said secondary waveguide and the secondary reflector of the secondary waveguide, so as to modulate the optical path length in said secondary waveguide.

8. The device according to claim 7, wherein each secondary waveguide comprises a secondary phase modulator, configured to modulate a refractive index along a portion of said secondary waveguide, the secondary phase modulator being placed between the coupling end of said secondary waveguide and the secondary reflector of said secondary waveguide, so as to modulate the optical path length in each secondary waveguide.

9. The device according to claim 1, wherein the primary waveguide comprises a primary phase modulator, configured to modulate a refractive index along a portion of the primary waveguide, the primary phase modulator being placed between each secondary waveguide and the primary reflector, so as to modulate the resonant wavelength of each Fabry-Pérot cavity of the device.

10. The device according to claim 1, wherein:
the primary reflector reflects more than 90% of the light, in the reflection spectral band;
each secondary reflector transmits at least 20% of the light, in the reflection spectral band, so that the secondary reflector forms the extractor of the device.

11. The device according to claim 1, wherein:
each secondary reflector reflects more than 90% of the light, in the reflection spectral band;
the primary reflector transmits at least 20% in the reflection spectral band, so that the primary reflector forms the extractor of the device.

12. The device according to claim 1, wherein the primary waveguide is formed by a first material, and surrounded by a first auxiliary material, the refractive index of which is lower than the refractive index of the first material.

13. The device according to claim 12, wherein each secondary waveguide is formed by a second material, and surrounded by a second auxiliary material, the refractive index of which is lower than the refractive index of the second material.

14. The device according to claim 13, wherein:
the first material is identical to the second material;
the first auxiliary material is identical to the second auxiliary material.

15. The device according to claim 14, wherein:
the first material and the second material are Si;
the first auxiliary material and the second auxiliary material are SiO2.

16. The device according to claim 13, wherein:
the first material is SiN;
the second material is Si;
the first auxiliary material is identical to the second auxiliary material.

17. The device according to claim 1, wherein the primary waveguide and each secondary waveguide are formed in the same substrate, each gain medium being transferred to said substrate.
